(19) United States
(12) Patent Application Publication
(10) Pub. No.: US 2026/0138213 A1
(43) Pub. Date: May 21, 2026

(54) BONDING APPARATUS AND A BONDING METHOD IMPLEMENTED BY THE SAME

(71) Applicant: STATS ChipPAC Management Pte. Ltd., Singapore (SG)

(72) Inventor: HyungSuk MIN, Incheon (KR)

(21) Appl. No.: 19/372,290

(22) Filed: Oct. 29, 2025

(30) Foreign Application Priority Data
Oct. 29, 2024 (CN) 202411521399.8

(51) Int. Cl. B23K 26/324; B23K 1/005; H10W 72/00; B23K 101/40

(52) U.S. Cl. CPC B23K 26/324; B23K 1/0056; H10W 72/07141; H10W 72/07188; B23K 2101/40

(57) ABSTRACT

A bonding apparatus and a bonding method are provided. The bonding apparatus comprises: a substrate carrier; a laser source for emitting a laser beam towards the substrate carrier; a compression tool movably disposed between the laser source and the substrate carrier, and configured for picking up a semiconductor die having a target bonding area and pressing the semiconductor die against the substrate, wherein the compression tool is transparent to the laser beam; and a beam shaping component disposed between the compression tool and the laser source, and configured for switchably shaping the laser beam between a preheating state and a bonding state, wherein in the bonding state the laser beam at least covers an entirety of the target bonding area, and in the preheating state the laser beam covers a portion of the target bonding area.

### TECHNICAL FIELD

The present application generally relates to semiconductor technology, and more particularly, to a bonding apparatus and a bonding method implemented by the bonding apparatus.

### BACKGROUND OF THE INVENTION

The semiconductor industry is constantly faced with complex integration challenges as consumers want their electronics to be smaller, faster and higher performance with more and more functionalities packed into a single device. In recent years, there is a growing application of laser compression bonding (LCB) technology in chip assembling processes due to its high bonding accuracy and efficiency.

With respect to an LCB process for bonding a semiconductor die onto a substrate, a laser source is used to emit a laser beam to the semiconductor die and the substrate to heat the semiconductor die, the substrate and solder paste therebetween. During this process, a transparent compression tool is disposed between the laser source and the semiconductor die, and operated to press the semiconductor die against the substrate to bond the semiconductor die onto the substrate. However, the laser beam irradiated to the semiconductor die and the substrate may have a non-uniform intensity. In other words, the laser beam may not focus well across an entirety of an irradiation area. For example, laser energy in a peripheral region of the irradiation area may be diminishing such that the peripheral region may not have sufficient energy to reflow the solder paste in the bonding process. This induces non-wetting of formed solder bumps and poor bonding performance between the semiconductor die and the substrate.

Therefore, a need exists for an apparatus and a method for bonding a semiconductor die onto a substrate with improved bonding quality.

### SUMMARY OF THE INVENTION

An objective of the present application is to provide an apparatus and a method for bonding a semiconductor die onto a substrate with improved bonding quality.

According to an aspect of the present application, a bonding apparatus is provided. The bonding apparatus comprises: a substrate carrier for placing a substrate thereon; a laser source for emitting a laser beam towards the substrate carrier; a compression tool movably disposed between the laser source and the substrate carrier, and configured for picking up a semiconductor die having a target bonding area and pressing the semiconductor die against the substrate, wherein the compression tool is transparent to the laser beam such that the laser beam passes through the compression tool to the semiconductor die when the semiconductor die is pressed against the substrate; and a beam shaping component disposed between the compression tool and the laser source, and configured for switchably shaping the laser beam between a preheating state and a bonding state, wherein in the bonding state the laser beam at least covers an entirety of the target bonding area, and in the preheating state the laser beam covers a portion of the target bonding area to preheat the semiconductor die.

According to another aspect of the present application, a method for bonding a semiconductor die onto a substrate is provided. The method comprises: placing a substrate on a substrate carrier; picking up a semiconductor die having a target bonding area via a compression tool disposed above the substrate carrier; placing the semiconductor die on the substrate via the compression tool; preheating a portion of the target bonding area of the semiconductor die by emitting a laser beam from a laser source to the substrate carrier through a beam shaping component and the compression tool, wherein the beam shaping component is disposed between the laser source and the substrate carrier and shapes the laser beam in a preheating state; switching the beam shaping component from the preheating state to a bonding state such that the laser beam emitted from the laser source at least covers an entirety of the target bonding area; and pressing the semiconductor die against the substrate via the compression tool to bond the semiconductor die onto the substrate when the beam shaping component is in the bonding state.

According to another aspect of the present application, a bonding apparatus is provided. The bonding apparatus comprises: a substrate carrier for placing a substrate thereon; a laser source for emitting a laser beam towards the substrate carrier; a compression tool movably disposed between the laser source and the substrate carrier, and configured for picking up a semiconductor die having a target bonding area and pressing the semiconductor die against the substrate, wherein the compression tool is transparent to the laser beam such that the laser beam passes through the compression tool to the semiconductor die when the semiconductor die is pressed against the substrate; and a beam shaping component disposed between the compression tool and the laser source, wherein the beam shaping component shapes the laser beam to cover at least an entirety of the target bonding area.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate a method for bonding a semiconductor die onto a substrate.

FIGS. 2A to 2G illustrate various steps of a method for bonding a semiconductor die onto a substrate implemented by a bonding apparatus according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

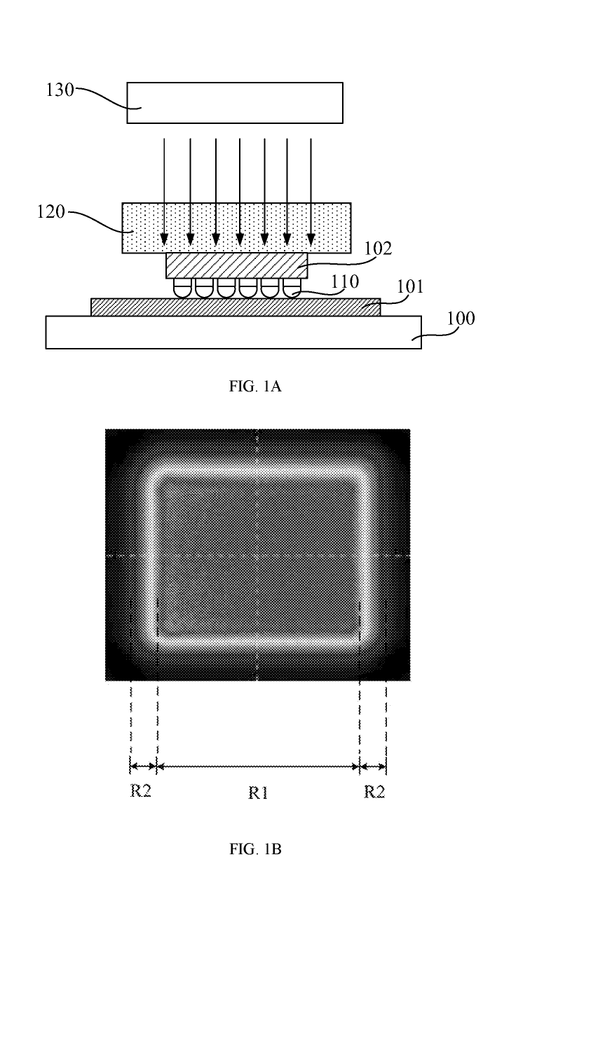

As mentioned above, laser compression bonding (LCB) technology is widely used in chip assembling processes due to its high bonding accuracy and efficiency. FIG. 1A illustrates an LCB process implemented by a bonding apparatus. As shown in FIG. 1A, a substrate 101 is placed on a substrate carrier 100. A semiconductor die 102 with solder paste 110 is picked up by a transparent compression tool 120 which is movably disposed above the substrate carrier 100. Then the semiconductor die 102 is placed on the substrate 101 by the compression tool 120. Next, a laser beam is emitted from a laser source 130 to the semiconductor die 102 through the transparent compression tool 120 to heat and reflow the solder paste 110. During the heating process, the semiconductor die 102 is pressed against the substrate 101 by the compression tool 120 to bond the semiconductor die 102 and the substrate 101 via the solder bumps which are transformed from the solder paste 110. Generally, the laser beam irradiated to the semiconductor die 102 may have a non-uniform intensity across its section. That is, the laser beam may not focus sharply when it reaches the semiconductor die 102, or particularly, laser energy in a peripheral region of an irradiation area of the laser beam may be diminishing compared with laser energy in a central region of the irradiation area, such that the semiconductor die 102 may not have sufficient energy in the peripheral region of the irradiation area of the laser beam to reflow the solder paste 110 there in the bonding process. To further illustrate this, FIG. 1B shows a top view of an exemplary irradiation area of a laser beam emitted from the laser source 130 in FIG. 1A. As shown in FIG. 1B, the irradiation area generated by the laser beam includes an effective irradiation region R1 at its center and a deteriorated irradiation region R2 outside the effective irradiation region R1. The deteriorated irradiation region R2 may not have sufficient energy as the laser intensity is lower, thereby the solder paste 110 below the portion of the semiconductor die 102 irradiated by or aligned with the deteriorated irradiation region R2 may not receive enough laser energy for the reflowing purpose. Thus, it may result in non-wetting of the solder bumps close to the periphery of the semiconductor die 102 and poor bonding performance between the semiconductor die 102 and the substrate 101.

To address this issue, a bonding apparatus for bonding a semiconductor die onto a substrate is provided. The bonding apparatus introduces a beam shaping component which is operable to shape a laser beam, and more particularly, to shape the laser beam between a preheating state and a bonding state. When the laser beam is shaped in the bonding state, it at least covers an entirety of a target bonding area of the semiconductor die. When the laser beam is shaped in the preheating state, it covers a portion of the target bonding area to preheat the semiconductor die with a uniform intensity. During the bonding process implemented by the bonding apparatus, the beam shaping component can adjust the intensity of the laser beam to achieve a uniform intensity. In this way, the entirety of the target bonding area of the semiconductor die is irradiated by the laser beam with sufficient laser energy during a bonding process to improve wetting of solder paste on the substrate. Moreover, the beam shaping component can be set to preheat the semiconductor die before the bonding process, which reduces warpage of the semiconductor die.

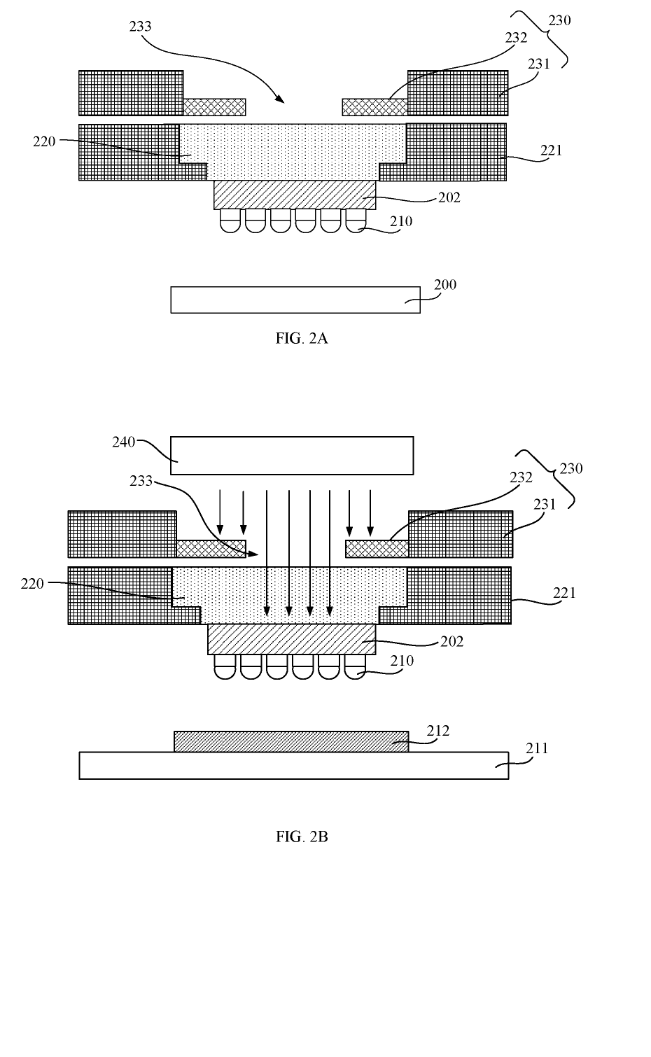

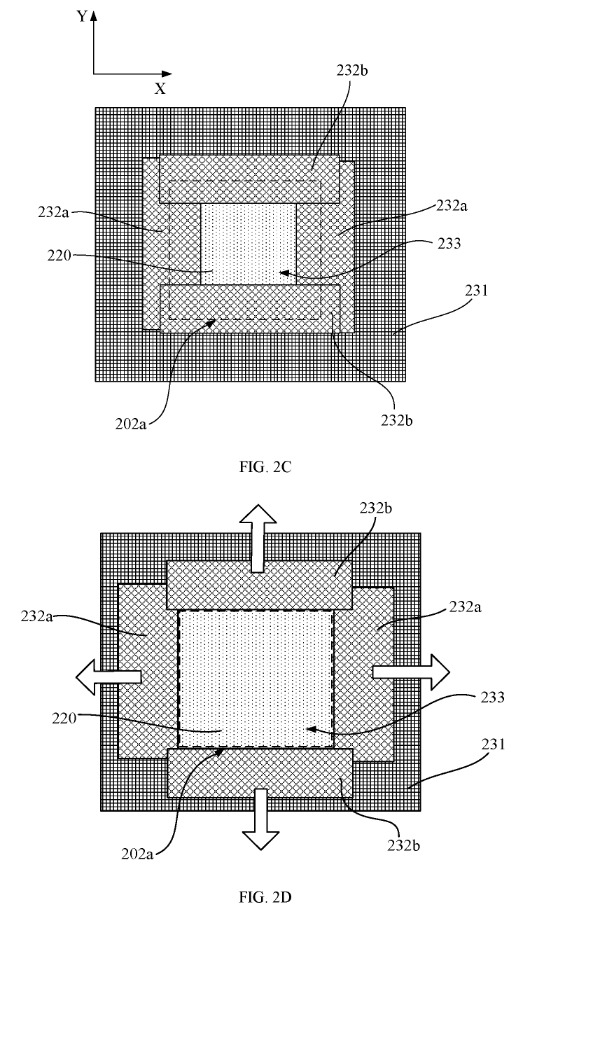

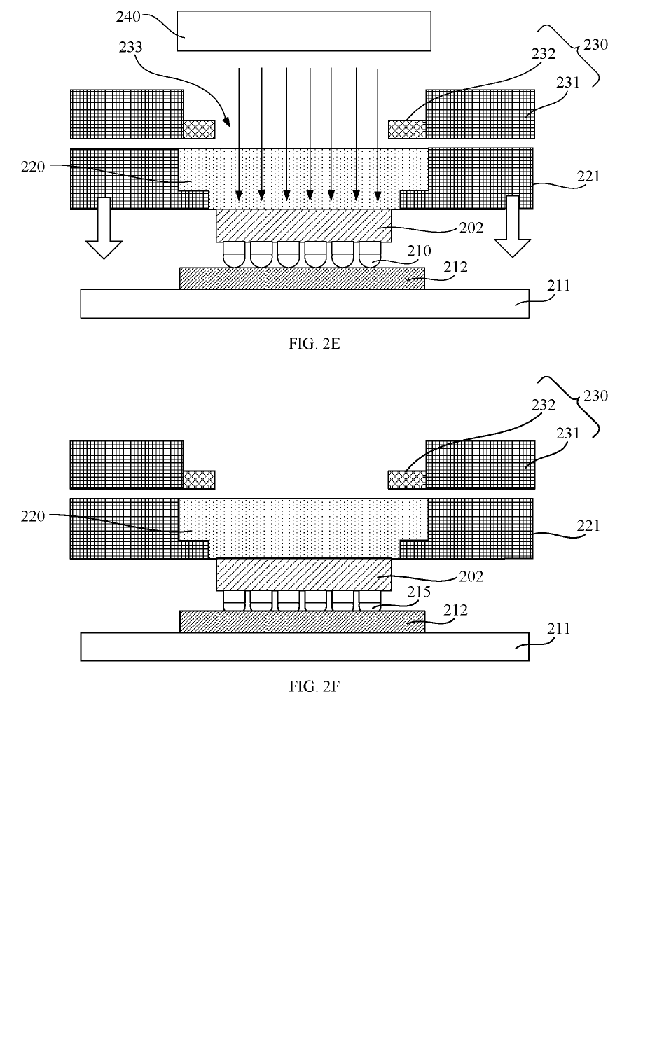

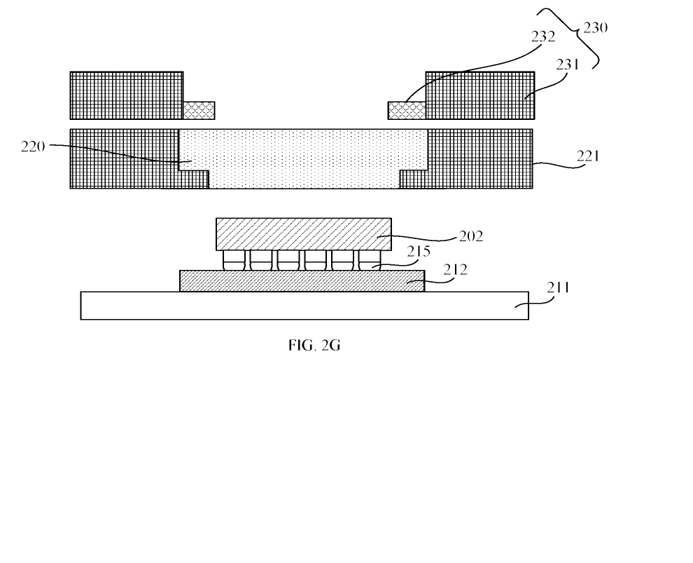

FIGS. 2A to 2G illustrate various steps of a method for bonding a semiconductor die onto a substrate which is implemented by a bonding apparatus according to an embodiment of the present application.

As shown in FIG. 2A, a compression tool 220 is used to pick up a semiconductor die 202 from a carrier 200 used in previous fabrication processes, for example, a flipper. In some embodiments, the semiconductor die 202 may include a flip chip, or some large-scale semiconductor chips such as a System on a Chip (SOC) die, an electronic package stack with multi-layer structures, or an electronic device or package having multiple electronic modules integrated therein. Conductive pads may be formed on a bottom surface of the semiconductor die 202 with a solder paste 210 dispensed thereon. Therefore, the semiconductor die 202 may be mounted onto an external module via the solder paste 210 in following processes. To be more specific, the semiconductor die 202 may have a target bonding area 202a which corresponds to a region where the solder paste 210 is applied, i.e., an area where the conductive pads reside. In a following bonding process, the target bonding area 202a needs to be sufficiently irradiated by a laser beam to form bonding between the semiconductor die 202 and external modules.

The compression tool 220 may include a compression head attached on a bottom surface of a compression base or formed with the compression base. In some embodiments, the size of the compression head may be substantially equal to or smaller than that of the compression base. The compression head may be in contact with the semiconductor die 202 when the semiconductor die 202 is picked up by the compression tool 220. In some embodiments, the compression head may have a rectangular layout, which may be similar to a shape of the semiconductor die 202. In some other embodiments, the compression head may have other shaped layouts, such as a circle, a hexagon or an octagon. In some embodiments, the compression base may have a size or layout that is the same as that of the compression head. It can be appreciated that the compression head may be formed separately from the compression base, or may be integrally formed with the compression base as a single piece. In this embodiment, the compression tool 220 may be formed of at least one transparent material selected from the following group: sapphire, quartz and glass, as a block, plate or any suitable structures. The transparent compression tool 220 allows a laser beam, which is applied in following processes, to substantially lossless pass through the compression tool 220 and reach the semiconductor die 202 and the solder paste 210. Furthermore, the compression head may have air vents extending therethrough, which can be fluidly coupled to a vacuum source to receive a vacuum pressure. The vacuum pressure can be further applied to the semiconductor die 202 through the air vents. In this way, the semiconductor die 202 can be firmly attracted to the compression tool 220 when it is picked up and transferred to a target place. As shown in FIG. 2A, a compression holder 221 is disposed outside of the compression tool 220, which mates with the compression tool 220 in size and shape to securely hold the compression tool 220. The compression holder 221 can provide mechanical support for the compression tool 220 when it is being used in the bonding process. In some embodiments, the compression holder 221 may include a light shading material which blocks laser beam to pass therethrough.

Still referring to FIG. 2A, a beam shaping component 230 is disposed above the compression tool 220. The beam shaping component 230 includes a beam shaping head 231 with an opening at its center, and a shutter 232 mounted to the beam shaping head 231 within the opening. In this embodiment, the shutter 232 protrudes horizontally from an inner surface of the beam shaping head 231 and defines an aperture 233 which is inside the opening of the beam shaping head 231. To be more specific, the beam shaping head 231 may be aligned with the compression holder 221, and the shutter 232 may be aligned with the compression tool 220 which covers at least a portion of the compression tool 220. The shutter 232 with the aperture 233 may serve as a slit to adjust the laser beam passing therethrough during the subsequent bonding process. Furthermore, in some embodiments, a size of the aperture 233 can be changed by horizontally moving the shutter 232 relative to the beam shaping head 231. As such, an irradiation area of the laser beam passing through the aperture 233 may be changed as required. In some other embodiments, the shutter 232 may be adjusted to change a shape of the aperture 233 therein. It can be appreciated that the shutter 232 may be formed of a non-transparent material, such that the laser beam may be partially blocked by the shutter 233. In some embodiments, the beam shaping component 230 may be mounted on the compression tool 220 such that it can be moved along with the movement of the compression tool 220. For example, the beam shaping component 230 can be fixed onto a top surface of the compression tool 220 via a fastener.

As shown in FIG. 2B, the semiconductor die 202 is displaced by the compression tool 220 to a position above a substrate 212. The semiconductor die 202 may be bonded onto the substrate 212 in the subsequent bonding process. In some embodiments, the substrate 212 may be made of silicon or other semiconductor materials, or may include a printed circuit board (PCB), a carrier substrate, a ceramic substrate, a laminate interposer, a strip interposer, a leadframe, or other suitable substrates. In some examples, the substrate 212 may include redistribution layers or structures having one or more dielectric layers and one or more conductive layers between and through dielectric layers. Thus, the various components and other structure on either one side or both sides of the substrate 212 may be electrically coupled with each other to form an integrated electronic system. In this embodiment, the substrate 212 is placed on a substrate carrier 211 for mechanical support. In some embodiments, the substrate carrier 211 may have air vents which are fluidly coupled to a vacuum source, so as to apply a vacuum pressure to the substrate 212 when it is disposed on the substrate carrier 211. The attraction force applied onto the substrate 212 which is generated by the vacuum pressure may reduce warpage of the substrate 212 during the subsequent bonding process. Multiple sets of conductive pads can be formed on a top surface of the substrate 212 for the mounting of the semiconductor die 202 on the substrate 212 via the solder paste 210.

Next, a laser beam is emitted from a laser source 240 disposed above the beam shaping component 230 to the substrate carrier 211. The laser beam passes through the aperture 233 of the shutter 232 and the compression tool 220 to reach the semiconductor die 202, so as to preheat the semiconductor die 202. FIG. 2C illustrates a top view of the beam shaping head 231 and the compression tool 220 shown in FIG. 2B. As shown in FIG. 2C, the beam shaping head 231 may have a rectangular outline. To be more specific, the beam shaping head 231 may have a shape of a straight-flanked ring with the opening at its center. The shutter 232 may have the rectangular aperture 233 inside the opening of the beam shaping head 231. The aperture 233 may expose a portion of the compression tool 220 which is aligned with a portion of the target bonding area 202a of the semiconductor die 202. As shown in FIG. 2C, the shutter 232 may include a first pair of blades 232a parallel to each other, and a second pair of blades 232b parallel to each other but perpendicular to the first pair of blades 232a. Each of the first and second pairs of blades 232a, 232b has a rectangular shape, and overlaps with adjacent blades to define the rectangular aperture 233. It can be appreciated that the aperture 233, the shutter 232 and the beam shaping head 231 may have other shapes. Each of the blades 232a, 232b may include an opaque material, such as stainless steel, and thus the shutter 232 covers a portion of the compression tool 220 to block a part of the laser beam from passing therethrough. To be more specific, a projection of the aperture 233 on the semiconductor die 202 may have a smaller coverage than the target bonding area 202a. In this way, with the blockage of the shutter 232, the laser beam passing through the aperture 233 and the compression tool 220 may have an irradiation region that covers only a portion of the target bonding area 202a to preheat the semiconductor die 202. For example, the irradiation region may cover 70% ~ 95% of the semiconductor die 202 for preheating. Also, it should be noted that a peripheral of the semiconductor die 202 may not be irradiated during the preheating process.

In some embodiments, the semiconductor die 202 may be preheated to a temperature between 85 °C and 150 °C for the preheating purpose. In some preferred embodiments, the semiconductor die 202 may be preheated to a temperature about 90 °C. The preheating process may last for a period of 2 seconds to 20 seconds, or preferably, 10 seconds to 20 seconds. In this embodiment, the preheating process may release thermal stress within the semiconductor die 202 and thus reduce warpage of the semiconductor die 202 generated in previous processes. For example, the preheating process may transform the semiconductor die 202 with a convex shape to an almost flat shape, which facilitates subsequent processes. In addition, the preheating of the semiconductor die 202 and the solder paste 210 may also reduce heat energy and a heating duration needed in the subsequent bonding process.

In the embodiment shown in FIGS. 2B and 2C, each blade of the first and second pairs of blades 232a, 232b is at least partially accommodated within the opening of the beam shaping head 231. The blades 232a, 232b are horizontally movable relative to the beam shaping head 231. To be more specific, the first pair of blades 232a are movable towards (or away from) each other in the lengthwise direction (X direction shown in FIG. 2C) of the beam shaping head 231, and the second pair of blades 232b are movable towards (or away from) each other in the widthwise direction (Y direction shown in FIG. 2C) of the beam shaping head 231. The size of the aperture 233 can then be changed by moving the first and second pairs of blades 232a, 232b such that the irradiation area of the laser beam passing through the aperture 233 and the compression tool 220 that reaches the semiconductor die 202 can be adjusted.

During the preheating process, the blades 232a, 232b may protrude from the beam shaping head 231 such that the aperture 233 has a reduced size that shapes the laser beam to cover the portion of the target bonding area 202a, which is referred to as a preheating state of the beam shaping component 230, as shown in FIGS. 2B and 2C. Moreover, as the aperture 233 defined by the blades 232a, 232b is smaller than the section of the laser beam, an outer portion of the laser beam, which may have a reduced intensity, can be blocked and cannot pass through the beam shaping component 230. In this way, the remaining portion of the laser beam, which is shaped by the shutter 232, has a better uniformity in intensity.

Next, the blades 232a, 232b may be moved towards the beam shaping head 231, for example, by respective actuators connected therewith, so as to enlarge the size of the aperture 233 until the blades 232a, 232b get to a position that defines the aperture 233 with an enlarged size as desired. That is, the aperture 233 shapes the laser beam to at least cover an entirety of the target bonding area 202a, where the beam shaping component 230 is in the bonding state, for implementing the subsequent bonding process of the semiconductor die 202 onto the substrate 212, as elaborated below. The reduced size and enlarged size of the aperture may be determined according to different sizes of the target bonding area 202a in different scenarios.

To be more specific, FIG. 2D illustrates the movement of the blades 232a, 232b as well as their updated positions after the movement. As shown in FIG. 2D, the first pair of blades 232a are moved away from each other in the lengthwise direction of the beam shaping head 231, and the second pair of blades 232b are moved away from each other in the widthwise direction of the beam shaping head 231 (illustrated by arrows in FIG. 2D). The movement of the first and second pairs of blades 232a, 232b may be implemented simultaneously or sequentially. During the movement of the blades 232a, 232b, the size of the aperture 233 may be gradually increased from the reduced size such that the exposed portion of the compression tool 220 may also be enlarged. Finally, the size of the aperture 233 may achieve the enlarged size where the projection of the aperture 233 on the semiconductor die 202 may overlap with or have a slightly larger coverage than the target bonding area 202a. At this point, the laser beam passing through the aperture 233 and the compression tool 220 at least covers the entire target bonding area 202a, as shown in FIG. 2D. As such, by moving the blades 232a, 232b, the beam shaping component 230 may be switched from the preheating state to the bonding state. In other words, during the preheating process, the irradiation area of the laser beam to the semiconductor die 202 is enlarged. In some preferred embodiments, the blades 232a, 232b may be gradually moved towards the beam shaping head 231. In this way, the temperature of the semiconductor die 202 may be gradually increased with the moving sequence of the blades 232a, 232b such that the entire target bonding area 202a of the semiconductor die 202 may be uniformly preheated to reduce the warpage of the semiconductor die 202 more efficiently.

In some embodiments, the beam shaping head 231 may include slots extending from the inner surface of the beam shaping head 231 into an interior of the beam shaping head 231. A portion of each of the blades 232a, 232b can be received within one of the slots during movement. It should be noted that a top portion of the beam shaping head 231 above the slots may be omitted in FIG. 2D to expose the entire structure of the shutter 232 for clarity. In some embodiments, stoppers or retention blocks may be arranged within each of the slots to limit further movements of the blades 232a, 232b when the aperture 233 reaches the enlarged size, which controls the irradiation to the target bonding area 202a preciously to avoid excessive heating of the semiconductor die 202 during the subsequent bonding process. The positions of the stoppers may be pre-set according to the size of the target bonding area 202a to indicate the position where the beam shaping component 230 achieves the bonding state. In some embodiments, a scale may be arranged on surfaces of the blades 232a, 232b indicating a distance they have been moved during the preheating process, which also helps to mark an end point of the movement. In some other embodiments, the blades 232a, 232b may be directly mounted on a front surface or a bottom surface of the beam shaping head 231 instead of protruding horizontally from an inner surface of the beam shaping head 231.

In some embodiments, the blades 232a, 232b are driven by a stepping motor or a linear motor to be moved relative to the beam shaping head 231. It can also be appreciated that a sensor coupled to the motor may be arranged below the compression tool 220. When the irradiation area of the laser beam covers the entirety of the target bonding area 202a, the sensor may receive a sensor signal and send out a stop signal to the motor, which terminates the movements of the blades 232a, 232b.

FIG. 2E illustrates a bonding process for bonding the semiconductor die 202 onto the substrate 212. The bonding process is implemented when the beam shaping component 230 is in the bonding state (as shown in FIG. 2D). The laser beam which has an irradiation area covering the entirety of the target bonding area 202a may heat the semiconductor die 202 and the solder paste 210 such that all of the solder paste 210 may be heated sufficiently, for example, to a temperature above its melting temperature. During the bonding process, the compression tool 220 is moved towards the substrate carrier 211 together with the beam shaping component 230 and the semiconductor die 202 until the solder paste 210 on the semiconductor die 202 is in contact with the substrate 212. Next, the semiconductor die 202 is pressed against the substrate 212 via a press force applied by the compression tool 220 to reshape the solder paste 210 to allow for sufficient infiltration on the substrate 212. This transforms the solder paste 210 into solder bumps which electrically connect the semiconductor die 202 and the substrate 212. Next, the press force applied by the compression tool 220 may gradually decrease to allow for solidification of the solder bumps.

Next, as shown in FIG. 2F, after the solder bumps 215 between the semiconductor die 202 and the substrate 212 are solidified, the laser source 240 may be turned off. Then the heating process implemented to the semiconductor die 202 and the solder bumps 215 is terminated, and the temperature of the semiconductor die 202 and the solder bumps 215 may begin to decrease to a lower temperature such as the room temperature. During the cooling of the solder bumps 215, the compression tool 220 may maintain at the bonding position for a while to help the solder bumps 215 solidify with a required bump height. Afterwards, the force applied by the compression tool 220 may also be removed and the shapes of the solder bumps 215 may not change, which enables stable joints between the semiconductor die 202 and the substrate 212 and thereby completes the bonding process.

In this embodiment, the compression tool 220, the beam shaping component 230, the laser source 240 and the substrate carrier 211 may all be a part of a bonding apparatus. The bonding method implemented by the bonding apparatus may provide several advantages. Firstly, during the bonding process, the beam shaping component 230 may provide direct adjustment of the laser beam when it is getting close to the semiconductor die 202, i.e., when it is about to pass through the compression tool 220, to focus laser energy within the laser beam. As such, the laser beam shaped by the beam shaping component 230 may have a uniform intensity when it reaches the semiconductor die 202 to focus sharply on the target bonding area 202a, which allows for sufficient laser energy across the entirety of the irradiation area of the laser beam when the beam shaping component 230 is in the bonding state. In this way, the entirety of the target bonding area 202a is irradiated by the laser beam with sufficient intensity, which allows all of the solder paste 210 below the target bonding area 202a to absorb adequate heat energy and avoids non-wetting. Therefore, the solder paste 210 may be fully reflowed and the formed solder bumps 215 may be more sufficiently infiltrated on the substrate 212, which improves the bonding quality between the semiconductor die 202 and the substrate 212. Secondly, since the laser beam may be focused better on the target bonding area 202a, the precision of the irradiation may be greatly improved, which may reduce potential risks of burning effect on the substrate 212 and the semiconductor die 202 due to overheating. Thirdly, since the shutter 232 included in the beam shaping component 230 is movable relative to the beam shaping head 231, it is convenient to move the shutter 232 to meet beam shaping requirements according to target bonding areas with different sizes. In addition, the shutter 232 may also be switched to shape the laser beam in the preheating state to preheat the semiconductor die 202 before the bonding process, which reduces warpage of the semiconductor die 202. In light of this, the beam shaping component 230 may be switched easily between the preheating state and the bonding state by simply moving the shutter 232 without additional procedures. Moreover, with the beam shaping component 230, the laser beam irradiated to the semiconductor die 202 during the preheating process may also be focused more sharply, thereby enhancing irradiation precision of the laser beam to preheat required areas during the preheating process.

In some other embodiments, the shutter 232 may include a first blade having an aperture with a reduced size and a second blade having an aperture with an enlarged size. Both of the first blade and the second blade may be an integrated piece with the aperture at its center, respectively. During the preheating process, the first blade and the second blade may be stacked together to shape the laser beam in the preheating state. During the bonding process, the first blade may be removed such that the laser beam may be shaped by the second blade in the bonding state.

In some alternative embodiments, the preheating process shown in FIGS. 2B and 2C may be omitted. Accordingly, the shutter may have a fixed configuration with an aperture which shapes the laser beam to cover at least the entirety of the target bonding area during the bonding process.

While the exemplary bonding apparatus and bonding method implemented by the bonding apparatus of the present application is described in conjunction with corresponding figures, it will be understood by those skilled in the art that modifications and adaptations to the bonding apparatus and bonding method implemented by the bonding apparatus may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A bonding apparatus, comprising:
a substrate carrier for placing a substrate thereon;
a laser source for emitting a laser beam towards the substrate carrier;
a compression tool movably disposed between the laser source and the substrate carrier, and configured for picking up a semiconductor die having a target bonding area and pressing the semiconductor die against the substrate, wherein the compression tool is transparent to the laser beam such that the laser beam passes through the compression tool to the semiconductor die when the semiconductor die is pressed against the substrate; and
a beam shaping component disposed between the compression tool and the laser source, and configured for switchably shaping the laser beam between a preheating state and a bonding state, wherein in the bonding state the laser beam at least covers an entirety of the target bonding area, and in the preheating state the laser beam covers a portion of the target bonding area to preheat the semiconductor die.

2. The bonding apparatus of claim 1, wherein the beam shaping component comprises:
a beam shaping head with an opening at its center; and
a shutter mounted to the beam shaping head and defining an aperture which is aligned with the opening of the beam shaping head, wherein the shutter is horizontally movable relative to the beam shaping head to change a size of the aperture, wherein
when the beam shaping component shapes the laser beam in the preheating state, the aperture has a reduced size that allows the laser beam to cover a portion of the target bonding area; and
when the beam shaping component shapes the laser beam in the bonding state, the aperture has an enlarged size that allows the laser beam to at least cover an entirety of the target bonding area.

3. The bonding apparatus of claim 2, wherein the shutter is driven by a stepping motor or a linear motor to move relative to the beam shaping head.

4. The bonding apparatus of claim 2, wherein the shutter is movable in a lengthwise direction of the beam shaping head and in a widthwise direction of the beam shaping head.

5. The bonding apparatus of claim 4, wherein the shutter comprises a first pair of blades which are movable towards each other in the lengthwise direction of the beam shaping head, and a second pair of blades which are movable towards each other in the widthwise direction of the beam shaping head.

6. The bonding apparatus of claim 1, wherein the substrate carrier has air vents being fluidly coupled to a vacuum source to apply a vacuum pressure to the substrate when the substrate is placed on the substrate carrier.

7. A method for bonding a semiconductor die onto a substrate, wherein the method comprises:
placing a substrate on a substrate carrier;
picking up a semiconductor die having a target bonding area via a compression tool disposed above the substrate carrier;
placing the semiconductor die on the substrate via the compression tool;
preheating a portion of the target bonding area of the semiconductor die by emitting a laser beam from a laser source to the substrate carrier through a beam shaping component and the compression tool, wherein the beam shaping component is disposed between the laser source and the substrate carrier and shapes the laser beam in a preheating state;
switching the beam shaping component from the preheating state to a bonding state such that the laser beam emitted from the laser source at least covers an entirety of the target bonding area; and
pressing the semiconductor die against the substrate via the compression tool to bond the semiconductor die onto the substrate when the beam shaping component is in the bonding state.

8. The method of claim 7, wherein the beam shaping component comprises:
a beam shaping head with an opening at its center; and
a shutter mounted to the beam shaping head and defining an aperture which is aligned with the opening of the beam shaping head, wherein the shutter is horizontally movable relative to the beam shaping head.

9. The method of claim 8, wherein preheating a portion of the target bonding area of the semiconductor die comprises:
shaping the laser beam in the preheating state via the beam shaping component such that the aperture has a reduced size that allows the laser beam to cover a portion of the target bonding area.

10. The method of claim 8, wherein switching the beam shaping component from the preheating state to a bonding state comprises:
moving the shutter horizontally relative to the beam shaping head to allow the aperture to have an enlarged size, so as to shape the laser beam in the bonding state that allows the laser beam to at least cover an entirety of the target bonding area.

11. The method of claim 10, wherein moving the shutter horizontally relative to the beam shaping head to allow the aperture to have an enlarged size is performed before pressing the semiconductor die against the substrate via the compression tool.

12. The method of claim 10, wherein moving the shutter horizontally relative to the beam shaping head comprises: moving the shutter in a lengthwise direction of the beam shaping head and in a widthwise direction of the beam shaping head.

13. A bonding apparatus, comprising:
a substrate carrier for placing a substrate thereon;
a laser source for emitting a laser beam towards the substrate carrier;
a compression tool movably disposed between the laser source and the substrate carrier, and configured for picking up a semiconductor die having a target bonding area and pressing the semiconductor die against the substrate, wherein the compression tool is transparent to the laser beam such that the laser beam passes through the compression tool to the semiconductor die when the semiconductor die is pressed against the substrate; and
a beam shaping component disposed between the compression tool and the laser source, wherein the beam shaping component shapes the laser beam to cover at least an entirety of the target bonding area.
